(19) United States
(12) Patent Application Publication
(10) Pub. No.: US 2022/0366229 A1
(43) Pub. Date: Nov. 17, 2022

(54) GATE BASED RESISTANCE CONTROL UNITS

(71) Applicant: Taiwan Semiconductor Manufacturing Co., Ltd., Hsinchu City (TW)

(72) Inventors: Mei-Chen CHUANG, Hsinchu City (TW); Chung-Hui CHEN, Hsin-Chu City (TW)

(21) Appl. No.: 17/318,810

(22) Filed: May 12, 2021

(51) Int. Cl. G06N 3/063

(52) U.S. Cl. CPC G06N 3/0635; G06N 3/08

(57) ABSTRACT

Disclosed are resistance control units based on gates, switches and/or memory cells. In one embodiment, a resistance control unit of a neural network formed on an integrated circuit (IC) is disclosed. The resistance control unit includes: a plurality of resistors coupled between a first node and a second node of the neural network; a plurality of switches coupled to the plurality of resistors and configured for controlling a current flowing from the first node to the second node; and a plurality of memory cells configured for generating a digital output. The plurality of switches can be controlled by the digital output.

### BACKGROUND

Neural networks, e.g. deep neural network (DNN) techniques, have demonstrated great success in machine learning applications such as pattern recognition and speech recognition. Training a neural network is an extremely computationally intensive task that requires massive computational resources and enormous training time that hinders their further application. Accelerator devices, e.g. a resistive processing unit (RPU), have been used to reduce training time and improve processing speed of the neural network, based on complementary-metal-oxide-semiconductor (CMOS) transistors with an analog weight update. First, these analog based accelerator devices would incur data retention issue due to leakage current and resistance drifting. That is, an analog based RPU would only provide a changing and unreliable weight value associated with the neural network. In addition, due to a complicated structure of an analog based RPU, the analog based RPU may cause a large circuit layout area and thus a large routing area, which induces processing difficulty and increases fabrication cost.

The information disclosed in this Background section is intended only to provide context for various embodiments of the invention described below and, therefore, this Background section may include information that is not necessarily prior art information (i.e., information that is already known to a person of ordinary skill in the art). Thus, work of the presently named inventors, to the extent the work is described in this background section, as well as aspects of the description that may not otherwise qualify as prior art at the time of filing, are neither expressly nor impliedly admitted as prior art against the present disclosure.

### BRIEF DESCRIPTION OF THE DRAWINGS

Aspects of the present disclosure are best understood from the following detailed description when read with the accompanying figures. It is noted that various features are not necessarily drawn to scale. In fact, the dimensions and geometries of the various features may be arbitrarily increased or reduced for clarity of illustration.

FIG. 1A illustrates a diagram of an exemplary neural network, in accordance with some embodiments of the present disclosure.

FIG. 1B illustrates a detailed diagram of a part of an exemplary neural network, in accordance with some embodiments of the present disclosure.

FIG. 2A illustrates an exemplary resistive processing unit in a neural network, in accordance with some embodiments of the present disclosure.

FIG. 2B illustrates another exemplary resistive processing unit in a neural network, in accordance with some embodiments of the present disclosure.

FIG. 2C illustrates yet another exemplary resistive processing unit in a neural network, in accordance with some embodiments of the present disclosure.

FIG. 3 illustrates an exemplary circuit in a resistive processing unit, in accordance with some embodiments of the present disclosure.

FIG. 4A illustrates an exemplary layout of gate structures in an integrated circuit, in accordance with some embodiments of the present disclosure.

FIG. 4B illustrates an exemplary layout of gate structures forming a resistor in a resistive processing unit, in accordance with some embodiments of the present disclosure.

FIG. 5A illustrates an array of resistive processing units in a neural network, in accordance with some embodiments of the present disclosure.

FIG. 5B illustrates a detailed diagram of an exemplary pair of resistive processing units, in accordance with some embodiments of the present disclosure.

FIG. 6 illustrates another array of resistive processing units in a neural network, in accordance with some embodiments of the present disclosure.

FIG. 7 illustrates an exemplary circuit of a pair of resistive processing units, in accordance with some embodiments of the present disclosure.

FIG. 8 shows a flow chart illustrating an exemplary method for operating a resistive processing unit in a neural network, in accordance with some embodiments of the present disclosure.

FIG. 9 shows a flow chart illustrating an exemplary method for designing a resistive processing unit in a neural network, in accordance with some embodiments of the present disclosure.

### DETAILED DESCRIPTION OF EXEMPLARY EMBODIMENTS

The following disclosure describes various exemplary embodiments for implementing different features of the subject matter. Specific examples of components and arrangements are described below to simplify the present disclosure. These are, of course, merely examples and are not intended to be limiting. For example, it will be understood that when an element is referred to as being “connected to” or “coupled to” another element, it may be directly connected to or coupled to the other element, or one or more intervening elements may be present.

This disclosure presents various embodiments of an array of resistance control units in a neural network formed on an integrated circuit (IC). In some embodiments, a resistance control unit may be a combination of gate based resistors coupled between a first node and a second node of the neural network, switches and memory cells, e.g. static random-access memory (SRAM), to form a resistor type memory cell to achieve a reliable resistive memory for computing in a neural network. Each resistor in the resistance control unit may be formed by connecting in series a plurality of gate structures in the IC using a plurality of gate vias on the plurality of gate structures, which makes it easy to design resistors with different resistances. With process migration and process shrinkage, a width W of the gate structures may be reduced, which makes it easy to achieve a larger resistance for the resistor. The memory cells in the resistance control unit may store and generate a digital output; and the switches may control a current flowing from the first node to the second node based on the digital output.

In some embodiments, at least one of the first node or the second node is located on a signal line in the memory cells to reduce the routing area. Accordingly, the resistance control unit may further include an additional switch to avoid malfunction in memory control. During a write mode of a memory cell, a read enable signal is set to make the additional switch open to ensure the memory cell is not affected by a previous state of the resistance control unit. During a computing mode of the neural network, the read enable signal is set to make the additional switch close to ensure the resistance control unit can work as a controllable resistor, which provides a weight value based on a conductance of the resistive processing unit between the first node and the second node. The weight value may be used for computing an output at the second node based on an input at the first node.

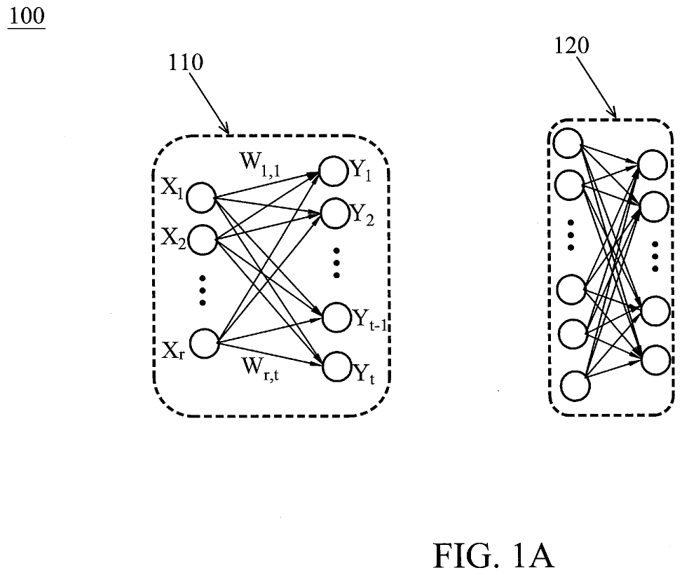

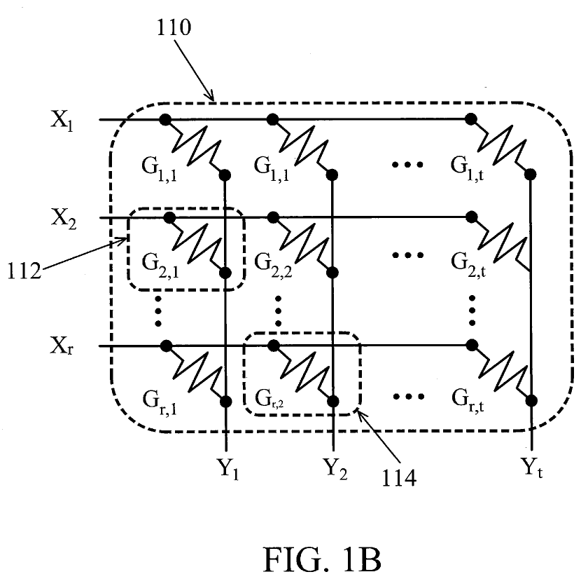

FIG. 1A illustrates a diagram of an exemplary neural network 100, in accordance with some embodiments of the present disclosure. As shown in FIG. 1A, the neural network 100 may include multiple stages 110, 120 connected in series, where outputs of a stage may serve as inputs to the next stage. Each stage of the neural network 100 may serve as a neural sub-network or an independent neural network in another embodiment, and have inputs, weights, and outputs. For example, the neural network (or sub-network) 110 has inputs Xᵢ; outputs Y_{q}; and weights W_{i,q}, where i=1 . . . r, q=1 . . . t. A stage output Y_{q} of the neural network 110 may be represented by: Y_{q}=Σᵢ₌₁W_{i,q}×Xi, where q=1 . . . t. Each stage output Y_{q} may serve as an input of next network stage.

FIG. 1B illustrates a detailed diagram of a part of an exemplary neural network, e.g. the neural network 110 in FIG. 1A, in accordance with some embodiments of the present disclosure. As shown in FIG. 1B, the neural network 110 may include an array of resistance control units 112, 114 connected between row and column lines of the neural network 110. In the example shown in FIG. 1B, each row line in the neural network 110 is associated with an input X of the neural network, i=1 . . . r; and each column line in the neural network 110 is associated with an output Y_{q} of the neural network, q=1 . . . t. Each of the resistance control units 112, 114 is coupled between a corresponding row line and a corresponding column line, and provides a weight value G_{i,q}, where i=1 . . . r, q=1 . . . t. For example, the resistance control unit 112 is coupled between a node A located on the row line X₂ and a node B located on the column line Yi, to provide a weight value G_{2,1} reflecting a relationship between the input X₂ and the output Yi in the neural network 110.

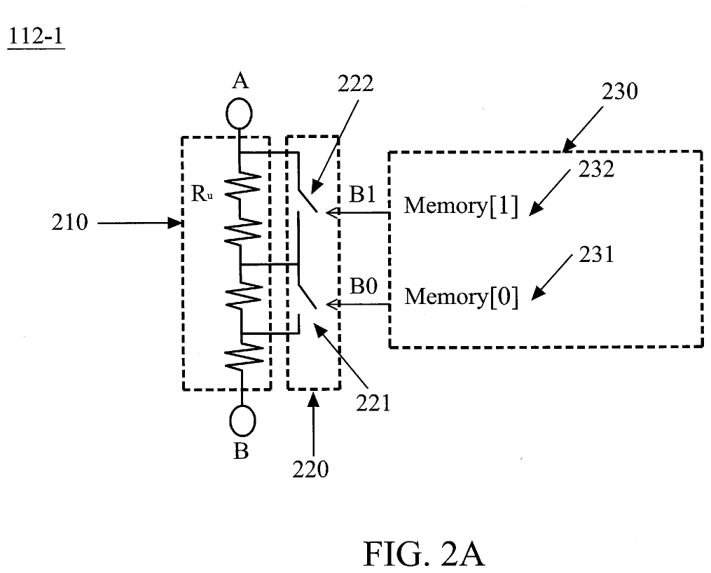

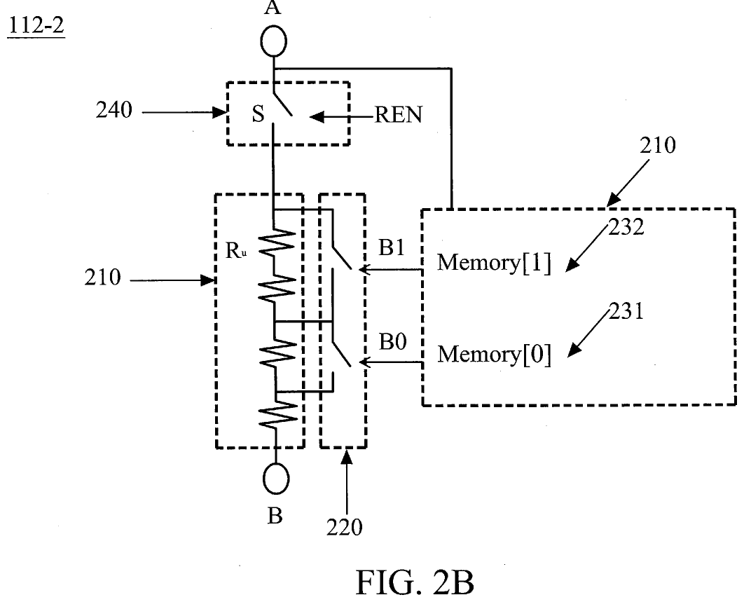

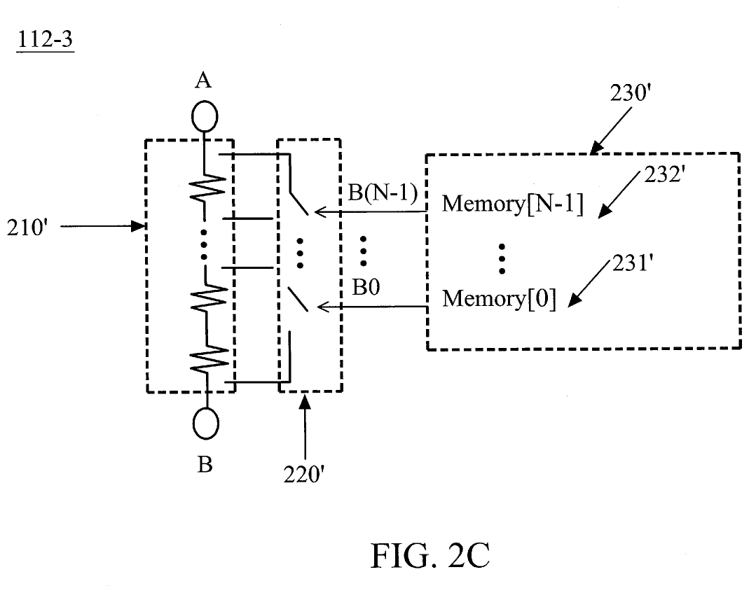

FIG. 2A illustrates an exemplary resistive processing unit 112-1 in a neural network, in accordance with some embodiments of the present disclosure. In some embodiments, the resistive processing unit 112-1 in FIG. 2A may serve as the resistive processing unit 112 in the neural network 110 in FIG. 1B. As shown in FIG. 2A, the resistance control unit 112-1 includes: a plurality of resistors 210 coupled between a first node A and a second node B of the neural network; a plurality of switches 220 coupled to the plurality of resistors 210; and a plurality of memory cells 230.

In the example shown in FIG. 2A, the plurality of resistors 210 includes four resistors Ru connected in series. In different embodiments, the four resistors may have a same resistance or different resistances. In some embodiments, the neural network is formed on an integrated circuit (IC); and at least one of the four resistors is formed by at least one gate structure and at least one gate via in the IC.

In the example shown in FIG. 2A, the plurality of switches 220 includes a first switch 221 and a second switch 222, which are configured for controlling a current flowing between the first node A and the second node B. The plurality of memory cells 230 may store and generate a digital output to control the plurality of switches 220. For example, the plurality of memory cells 230 includes a memory cell 231 corresponding to a first bit B0 of the digital output, and a memory cell 232 corresponding to a second bit B1 of the digital output. The first bit B0 read from the memory cell 231 provides an indication to control the state of the first switch 221; and the second bit B1 read from the memory cell 232 provides an indication to control the state of the second switch 222. For each bit, a bit value 1 may indicate turning on a corresponding switch; while a bit value 0 may indicate turning off the corresponding switch. As such, in the example shown in FIG. 2A, when each of the four resistors 210 has a resistance Ru, an equivalent resistance between the node A and the node B is equal to Ru when B1=1 and B0=1, because three of the four resistors are shorted out by the closed switches 221, 222. Similarly, when each of the four resistors 210 has a resistance Ru, an equivalent resistance between the node A and the node B is: equal to 2Ru when B1=1 and B0=0; equal to 3Ru when B1=0 and B0=1; and equal to 4Ru when B1=0 and B0=0.

In some embodiments, each of the plurality of switches 220 may be formed by at least one transistor; and each of the at least one transistor may be connected, in series or in parallel, to at least one of the plurality of resistors 210. In some embodiments, each of the plurality of memory cells is a static random-access memory (SRAM) formed by a plurality of transistors.

FIG. 2B illustrates another exemplary resistive processing unit 112-2 in a neural network, in accordance with some embodiments of the present disclosure. In some embodiments, the resistive processing unit 112-2 in FIG. 2B may serve as the resistive processing unit 112 in the neural network 110 in FIG. 1B. Similar to the resistive processing unit 112-1 in FIG. 2A, the resistance control unit 112-2 in FIG. 2B includes: a plurality of resistors 210 coupled between a first node A and a second node B of the neural network; a plurality of switches 220 coupled to the plurality of resistors 210; and a plurality of memory cells 230. Different from the resistive processing unit 112-1 in FIG. 2A, the resistance control unit 112-2 in FIG. 2B also includes an additional switch S 240 coupled between the first node A and the plurality of resistors 210.

In some embodiments, the switch S 240 serves as a read enable switch controlled by a read enable signal REN. The switch S 240 can help to avoid malfunction in memory control, especially when the first node A, the second node B, or both nodes are located on or shared with a signal line in the memory cells 231, 232 to reduce the routing area during IC fabrication.

In some embodiments, the read enable switch 240 is set to open state by the read enable signal REN during a write mode of the plurality of memory cells 230, to ensure the memory cells 230 are not affected by a previous state of the resistance control unit 112-2. In some embodiments, the read enable switch 240 is set to close state by the read enable signal REN during a computing mode of the neural network, to ensure the resistance control unit 112-2 can work as a controllable or tunable resistor to provide a weight value based on a conductance of the resistive processing unit 112-2 between the first node A and the second node B. The formation and other operations of the resistance control unit 112-2 in FIG. 2B may be similar to the formation and operations of the resistive processing unit 112-1 in FIG. 2A.

FIG. 2C illustrates yet another exemplary resistive processing unit 112-3 in a neural network, in accordance with some embodiments of the present disclosure. In some embodiments, the resistive processing unit 112-3 in FIG. 2C may serve as the resistive processing unit 112 in the neural network 110 in FIG. 1B. Similar to the resistive processing unit 112-1 in FIG. 2A, the resistance control unit 112-3 in FIG. 2C includes: a plurality of resistors 210′ coupled between a first node A and a second node B of the neural network; a plurality of switches 220′ coupled to the plurality of resistors 210′; and a plurality of memory cells 230′. Different from the resistive processing unit 112-1 in FIG. 2A, the resistance control unit 112-3 in FIG. 2C includes: M resistors 210′, N switches 220′ and N memory cells 230′, where M and N can be any positive integers. Each of the N switches 220′ may be controlled by a respective one of the N bits B0 . . . B(N−1) read from the N memory cells 230′ respectively. In some embodiments, the number of switches 220′ may be different from the number of the memory cells 230′. In some embodiments, the formation and operations of the resistance control unit 112-3 in FIG. 2C may be similar to the formation and operations of the resistive processing unit 112-1 in FIG. 2A.

In some embodiments, a conductance between the first node A and the second node B provides a weight value associated with the neural network; and the conductance changes linearly based on different states of the plurality of switches 220′. For example, the resistance control unit 112-3 in FIG. 2C may provide a N-bit weight based on different conductance values increasing linearly from G to (2^{N})*G. Accordingly, the equivalent resistance of the resistance control unit 112-3 between the first node A and the second node B can vary from (½^{N})*(1/G) to 1/G. That is, to achieve linearly distributed weights, the equivalent resistance of the resistance control unit 112-3 may be equal to 1/G, 2/G, 3/G . . . (2^{N})*(1/G), according to different state combinations of the switches 220′.

In some embodiments, the value of G can be determined based on a unit resistance Ru, according to an equation: (½^{N})*(1/G)=Ru. The relationship between G and Ru may follow other equations in other embodiments. The unit resistance Ru may be determined by forming a unit resistor based on one or more metal gates in the IC. The quantity N of memory cells and the quantity of switches in the resistance control unit 112-3 may be predetermined. Each of the N memory cells may be a SRAM including a plurality of transistors, e.g. 6 transistors or 8 transistors, configured for storing digital values to control the switches.

In some embodiments, when a switch is turned off, an equivalent resistance is from a resistor path which is formed by one or more metal gates; when the switch is turned on, a current path is shortened to bypass the resistor path and make an equivalent resistance along the current path at least 10 times smaller than the equivalent resistance along the resistor path. As such, an equivalent resistance between the node A and the node B can be counted by designing on/off states of the switches 220′, coupling locations of the switches 220′, and the unit resistance Ru based on gate structures. To use the N-bit weight in a neural network, the N-bit weight can be stored by the memory cells 230′, such that the weight can be modified or updated by updating the bits stored in the memory cells 230′.

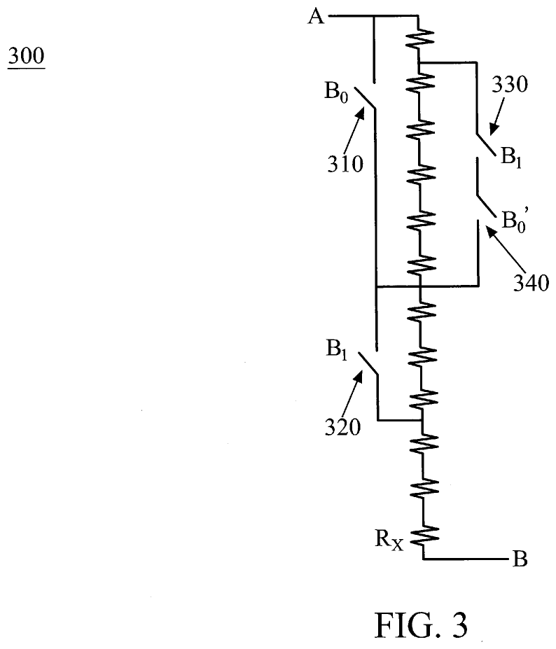

FIG. 3 illustrates an exemplary circuit 300 in a resistive processing unit, in accordance with some embodiments of the present disclosure. As shown in FIG. 3, the circuit 300 includes 12 resistors connected in series between node A and node B; a switch 310 controlled by a bit B0; a switch 320 controlled by a bit B1; a switch 330 controlled by the bit B1; and a switch 340 controlled by a bit B0′, where the bit B0′ always has an opposite bit value compared to the bit B0. It can be understood that in other embodiments, at least some of the resistors in a resistive processing unit may be connected in parallel.

In the example shown in FIG. 3, each of the 12 resistors has a resistance Rx. According to the coupling locations of the switches 310, 320, 330, 340, an equivalent resistance between the node A and the node B is equal to 12Rx when B1=0 and B0=0 (i.e. B0′=1), because the switches 310, 320, 330 are open and no resistor of the 12 resistors is shortened out. Similarly, an equivalent resistance between the node A and the node B is: equal to 6Rx when B1=0 and B0=1; equal to 4Rx when B1=1 and B0=0; and equal to 3Rx when B1=1 and B0=1.

In some embodiments, a unit resistance Ru is equal to Rx*¾, and a unit conductance is equal to 1/(12Rx). As such, when B1=0 and B0=0, the resistive processing unit has an equivalent conductance of G and an equivalent resistance of 16Ru; when B1=0 and B0=1, the resistive processing unit has an equivalent conductance of 2G and an equivalent resistance of 8Ru; when B1=1 and B0=0, the resistive processing unit has an equivalent conductance of 3G and an equivalent resistance of 5.33Ru; and when B1=1 and B0=1, the resistive processing unit has an equivalent conductance of 4G and an equivalent resistance of 4Ru. Therefore, the resistive processing unit between the node A and the node B can provide linearly distributed weights based on the linearly distributed conductance G to 4G according to different bit state combinations of the bits B1 and B0.

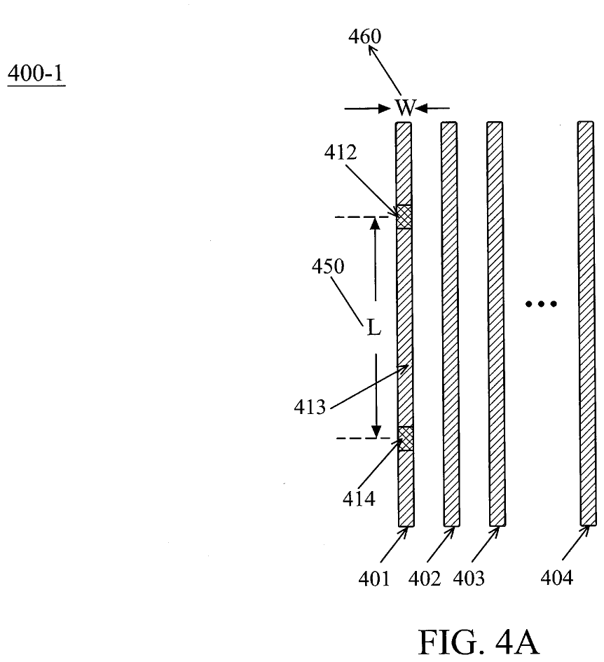

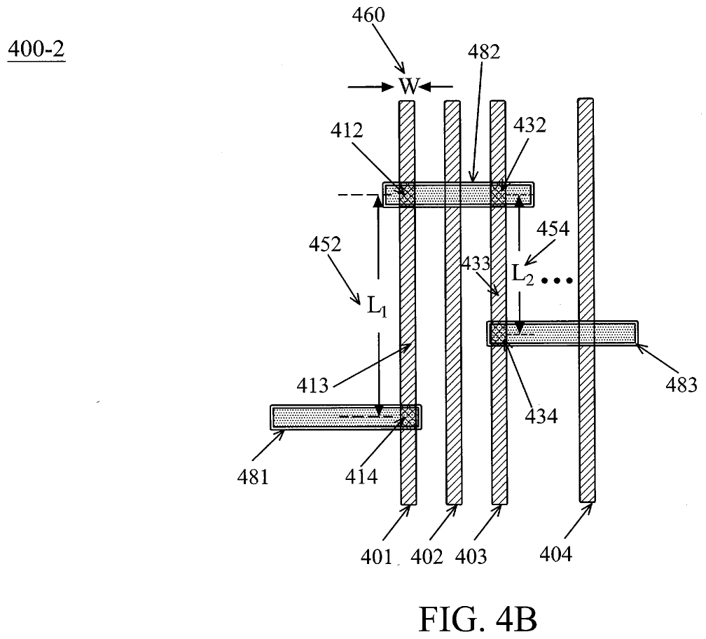

FIG. 4A illustrates an exemplary layout of gate structures in an integrated circuit 400-1, in accordance with some embodiments of the present disclosure. As shown in FIG. 4A, the integrated circuit 400-1 includes a plurality of gate lines 401, 402, 403, 404. In some embodiments, all gate lines 401, 402, 403, 404 have a same width W 460, which may be determined by a fabrication process. In some embodiments, the gate lines 401, 402, 403, 404 may provide gates for transistors in the integrated circuit 400-1. Each gate line may have a plurality of gate contacts or gate vias located on the gate line, e.g. to provide routing for the gates. For example, two gate vias 412, 414 are located on the gate line 401. The portion of the gate line 401 between the two gate vias 412, 414 may be referred to as a gate structure 413 with a length L 450. Although not shown, it can be understood that there may be multiple gate structures in the integrated circuit 400-1. In some embodiments, an equivalent resistance Rx of the gate structure 413 can be calculated based on Rx=R_{SEQ}*L/W, where R_{SEQ} is a parameter related to process and may be equal to 300 in some embodiments.

FIG. 4B illustrates an exemplary layout of gate structures forming a resistor in a resistive processing unit formed on an integrated circuit 400-2, in accordance with some embodiments of the present disclosure. In some embodiments, the integrated circuit 400-2 in FIG. 4B is the same as the integrated circuit 400-1 in FIG. 4A, except that a plurality of metal lines 481, 482, 483 are formed on a plurality of gate contacts 412, 414, 432, 434 to form a resistor in a resistive processing unit. As shown in FIG. 4B, the resistor is formed by two gate structures 413, 433 connected in series by the gate contacts 412, 414, 432, 434 and the upper metal lines 481, 482, 483. While the gate structure 413 has a length L1 452, the gate structure 433 has a length L2 454. In some embodiments, the length L1 452 and the length L2 454 can be designed arbitrary based on where to put the gate contacts 412, 414, 432, 434 to connect to the upper metal lines for connections with switches in the resistive processing unit. In some embodiments, each gate structure and each gate via may be formed by a polysilicon or a metal material. In some embodiments, the metal lines 481, 482, 483 have a much lower resistance than the gate structures 413, 433 and the gate contacts 412, 414, 432, 434, such that an equivalent resistance Rx of the resistor in the resistive processing unit can be calculated based on Rx=300*(L1+L2)/W+4*Vg, where Vg is equal to a resistance of each gate contact or gate via.

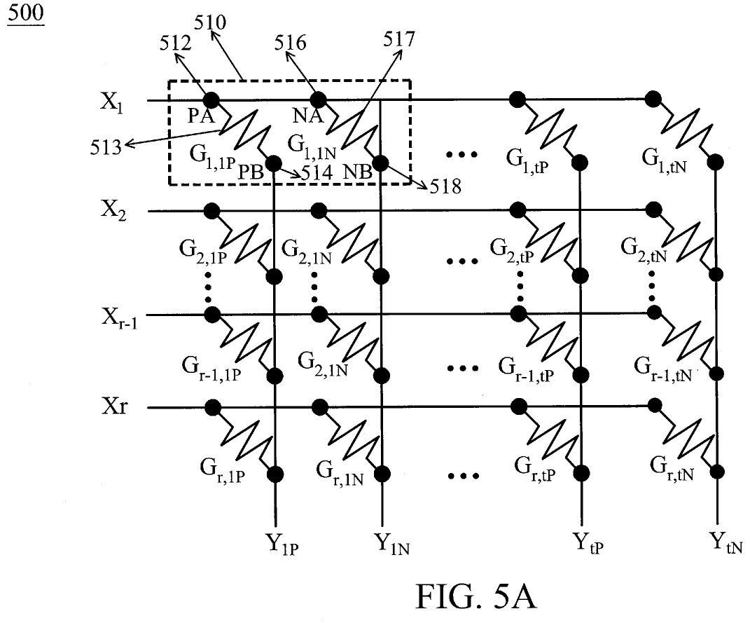

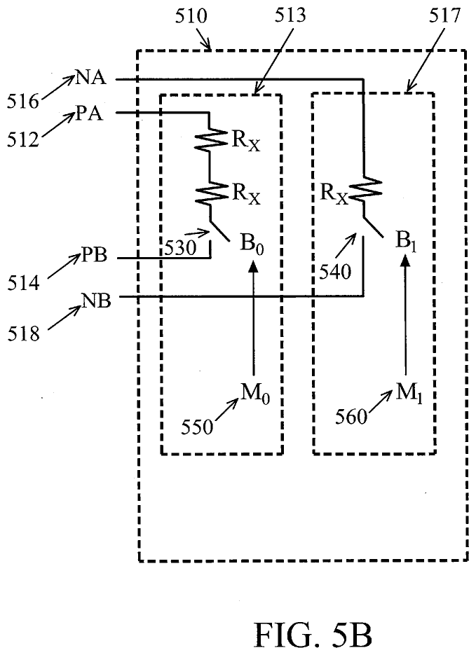

FIG. 5A illustrates an array of resistive processing units in a neural network 500, in accordance with some embodiments of the present disclosure. In some embodiments, the array of resistive processing units in the neural network 500 is used to perform machine learning without backpropagation. As shown in FIG. 5A, the neural network 500 includes an array of resistance control units connected between row and column lines of the neural network 500. In the example shown in FIG. 5A, each row line in the neural network 500 is associated with an input Xᵢ of the neural network, i=1 . . . r; and each column line in the neural network 500 is associated with an output Y_{qP} or Y_{qN} of the neural network 500, q=1 . . . t. The column lines include a plurality of pairs of column lines, where each pair of column lines is associated with a pair of outputs (Y_{qP} and Y_{qN}) of the neural network 500.

The resistance control units include a plurality of pairs of resistance control units, where each pair of resistance control units is coupled between a corresponding row line and a corresponding pair of column lines, and provides a positive weight value G_{i,qP} and a negative weight value G_{i,qN}, where i=1 . . . r, q=1 . . . t. For example, the resistance control unit pair 510 is coupled between the row line X₁ and a corresponding pair of column lines Y_{1P} and Y_{1N} of the neural network 500. To be specific, the resistance control unit pair 510 includes: a first resistance control unit 513 between the row line X₁ and the column line Y_{1P}; and a second resistance control unit 517 between the row line X₁ and the column line Y_{1N}. As shown in FIG. 5A, the first resistance control unit 513 is coupled between a node PA 512 located on the row line X₁ and a node PB 514 located on the column line Y_{1P}; and the second resistance control unit 517 is coupled between a node NA 516 located on the row line X₁ and a node NB 518 located on the column line Y_{1N}. The node PA 512 and the node NA 516 are electrically shortened to each other in this case. The first resistance control unit 513 has a first conductance G_{1,1P}, which provides a positive weight associated with the input X₁ and the output Y_{1P}. The second resistance control unit 517 has a second conductance G_{1,1N}, which provides a negative weight associated with the input X₁ and the output Y_{1N}. As such, the first resistance control unit 513 and the second resistance control unit 517 in the resistance control unit pair 510 together provide a signed weight, based on a summation of the positive weight and the negative weight, to reflect a relationship between the input X₁ and an output pair of the outputs Y_{1P} and Y_{1N} in the neural network 500.

FIG. 5B illustrates a detailed diagram of an exemplary pair of resistive processing units, e.g. the resistance control unit pair 510 or any other resistance control unit pair in FIG. 5A, in accordance with some embodiments of the present disclosure. As shown in FIG. 5B, the resistance control unit pair 510 includes: a resistance control unit 513 coupled between a node PA 512 and a node PB 514; and a resistance control unit 517 coupled between a node NA 516 and a node NB 518. The resistance control unit 513 includes: two resistors Rx connected in series between the node PA 512 and the node PB 514; a switch 530 coupled between the node PB 514 and the two resistors Rx; and a memory cell M0 550 configured for generating a bit B0 to control the switch 530. The resistance control unit 517 includes: one resistor Rx connected between the node NA 516 and the node NB 518; a switch 540 coupled between the node NB 518 and the one resistor Rx; and a memory cell M1 560 configured for generating a bit B1 to control the switch 540. While there are in total two bits stored in the resistance control unit pair 510 for controlling resistance and conductance of the resistance control unit pair 510, any other number of bits can be used in different embodiments of the present disclosure.

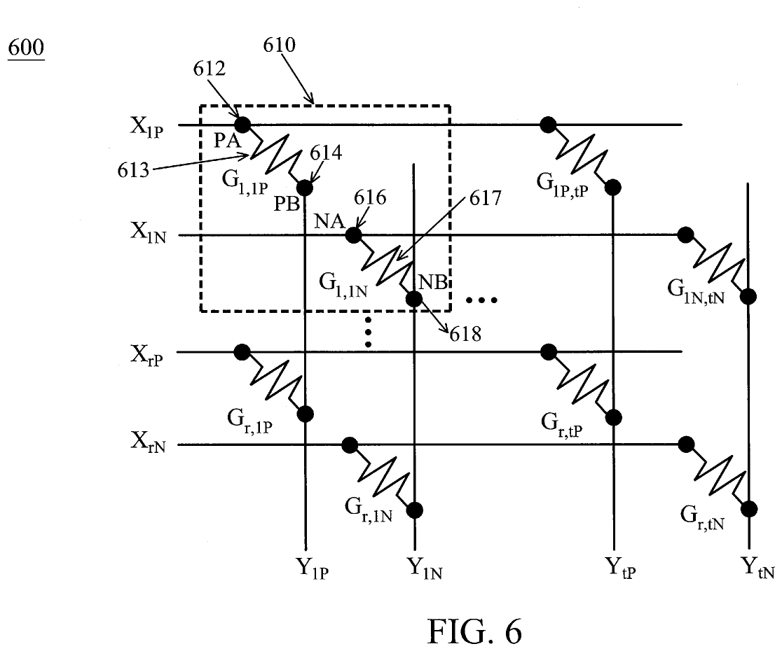

FIG. 6 illustrates another array of resistive processing units in a neural network 600, in accordance with some embodiments of the present disclosure. In some embodiments, the array of resistive processing units in the neural network 600 is used for performing a machine learning with backpropagation. As shown in FIG. 6, the neural network 600 includes an array of resistance control units connected between row and column lines of the neural network 600. In the example shown in FIG. 6, each row line in the neural network 600 is associated with an input X_{1P} or X_{1N} of the neural network, i=1 . . . r; and each column line in the neural network 600 is associated with an output Y_{q}P or Y_{q}N of the neural network 600, q=1 . . . t. The row lines include a plurality of pairs of row lines, where each pair of row lines is associated with a pair of inputs (X_{1P} and X_{1N}) of the neural network 600. The column lines include a plurality of pairs of column lines, where each pair of column lines is associated with a pair of outputs (Y_{qP} and Y_{qN}) of the neural network 600.

The resistance control units include a plurality of pairs of resistance control units, where each pair of resistance control units is coupled between a corresponding pair of row lines and a corresponding pair of column lines, and provides a positive weight value G_{1,qP} and a negative weight value G_{1,qN}, where i=1 . . . r, q=1 . . . t. For example, the resistance control unit pair 610 is coupled between (a) a corresponding pair of row lines X_{1P} and X_{1N} and (b) a corresponding pair of column lines Y_{1P} and Y_{1N} of the neural network 600. To be specific, the resistance control unit pair 610 includes: a first resistance control unit 613 between the row line X_{1P} and the column line Y_{1P}; and a second resistance control unit 617 between the row line X_{1N} and the column line Y_{1N}. As shown in FIG. 6, the first resistance control unit 613 is coupled between a node PA 612 located on the row line X_{1P} and a node PB 614 located on the column line Y_{1P}; and the second resistance control unit 617 is coupled between a node NA 616 located on the row line X_{1N} and a node NB 618 located on the column line Y_{1N}. The node PA 612 and the node NA 616 are not electrically shortened in this case. The first resistance control unit 613 has a first conductance G_{1,1P}, which provides a positive weight associated with the input X_{1P} and the output Y_{1P}. The second resistance control unit 617 has a second conductance G_{1,1N}, which provides a negative weight associated with the input X_{1N} and the output Y_{1N}. As such, the first resistance control unit 613 and the second resistance control unit 617 in the resistance control unit pair 610 together provide a signed weight, based on a summation of the positive weight and the negative weight, to reflect a relationship between (a) an input pair of the inputs X_{1P} and X_{1N} and (b) an output pair of the outputs Y_{1P} and Y_{1N}, in the neural network 600.

In some embodiments, a conductance of each resistive processing unit between two nodes of the neural network 600 provides a weight value associated with the neural network 600. In some embodiments, the resistive processing units in the neural network 600 are configured for performing bidirectional communications along the row and column lines based on the weight values provided by the resistive processing units. In some embodiments, each resistance control unit pair, e.g. the resistance control unit pair 610, may have a diagram shown in FIG. 5B.

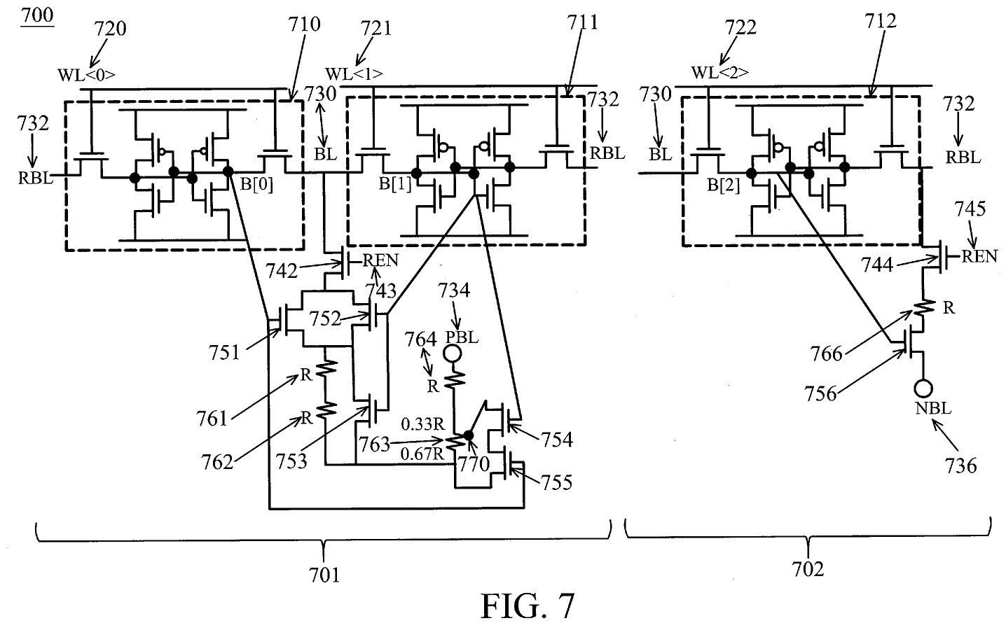

FIG. 7 illustrates an exemplary circuit 700 of a pair of resistive processing units 701, 702, in accordance with some embodiments of the present disclosure. The resistive processing unit 701 provides a positive weight between bit line BL 730 and a positive bit line PBL 734 based on two bits B[0], B[1] stored in the memory cells 710, 711 respectively. The resistive processing unit 702 provides a negative weight between replica bit line RBL 732 and a negative bit line NBL 736 based on one bit B[2] stored in the memory cell 712.

As shown in FIG. 7, the resistive processing unit 701 includes: four resistors 761, 762, 763, 764 connected in series between the BL 730 and the PBL 734; switches 751, 752, 753, 754, 755 coupled to the resistors 761, 762, 763, 764 and configured for controlling a current flowing from the BL 730 to the PBL 734; and the memory cells 710, 711 configured for storing and generating bits B[0], B[1] used to control the switches 751, 752, 753, 754, 755. The resistive processing unit 702 includes: one resistor 766 connected between the RBL 732 and the NBL 736; a switch 756 coupled between the resistor 766 and the NBL 736 and configured for controlling a current flowing from the RBL 732 to the NBL 736; and the memory cell 712 configured for storing and generating bit B[2] used to control the switch 756. Since the resistive processing unit 701 and the resistive processing unit 702 are coupled between signal lines (bit lines) of the memory cells, each of the resistive processing unit 701 and the resistive processing unit 702 includes a read enable switch to avoid malfunction in memory control. For example, the resistive processing unit 701 includes a read enable switch 742 coupled between the BL 730 and the resistors 761, 762, 763, 764, and controlled by a read enable signal REN 743; and the resistive processing unit 702 includes a read enable switch 744 coupled between the RBL 732 and the resistor 766, and controlled by a read enable signal REN 745. Each of the REN 743 and the REN 745 may be a control voltage. In some embodiments, the REN 743 and the REN 745 are the same signal, and may be the same for an entire array including the pair of resistive processing units 701, 702. In some embodiments, each of the switches 742, 744 is formed by a transistor, whose gate is controlled the REN signal.

In the example shown in FIG. 7, each of the memory cells 710, 711, 712 is a 6-transistor SRAM memory, while another type of memory cell can be used in other embodiments. The memory cell 710 is connected to word line WL<0> 720, the RBL 732, and the BL 730; the memory cell 711 is connected to word line WL<1> 721, the RBL 732, and the BL 730; and the memory cell 712 is connected to word line WL<2> 722, the RBL 732, and the BL 730.

In the example shown in FIG. 7, each of the switches 751-756 is formed by a transistor, whose gate is controlled by a bit read from a corresponding memory cell. For example, gates of the switches 751, 755 are coupled to and controlled by bit B[0] read from the memory cell 710; gates of the switches 752, 753, 754 are coupled to and controlled by bit B[1] read from the memory cell 711; and gate of the switch 756 is coupled to and controlled by bit B[2] read from the memory cell 712.

As shown in FIG. 7, the switches 751, 752 are coupled between the switch 742 and the resistor 761; the switch 753 is connected in parallel to the resistors 761, 762. The switches 754, 755 are connected to each other in series, and are connected in parallel to a portion of the resistor 763. In some embodiments, the portion may have a resistance equal to ⅔ of the resistance of the entire resistor 763.

In some embodiments, during a write mode of a memory cell, the REN signal is set to make the switches 742, 744 open, to ensure the memory cell is not affected by the previous state of the resistive processing unit 701 or the resistive processing unit 702. During a computing mode, the REN signal is set to make the switches 742, 744 close to enable a controllable resistor between the RBL 732 and the NBL 736, and a controllable resistor between the BL 730 and the PBL 734. In some embodiments, a current can flow from the BL 730 to the PBL 734 along a forward path for computing; or from the PBL 734 to the BL 730 along a backward path for training, depending on forward path or backward path of the neural network operations. Similarly, a current can flow from the RBL 732 to the NBL 736 along a forward path for computing; or from the NBL 736 to the RBL 732 along a backward path for training, depending on forward path or backward path of the neural network operations.

In some embodiments, each of the resistors 761, 762, 763, 764, 766 has a same resistance R. As such, when B[2:0]=111, the switch 766 is closed and the switches 751, 752, 753, 754, 755 are closed as well. Accordingly, an equivalent resistor in the resistive processing unit 702 between the RBL 732 and the NBL 736 is R; and an equivalent resistor in the resistive processing unit 701 between the BL 730 and the PBL 734 is 1.33R, as the other resistors are shorted out by the closed switches 751, 752, 753, 754, 755. In this case, an equivalent conductance of the resistive processing unit 701 is 0.75G=1/(1.33R) with a positive weight sign; and an equivalent conductance of the resistive processing unit 702 is G=1/R with a negative weight sign. As such, a total equivalent conductance of the pair of resistive processing units 701, 702 is equal to 0.75G−1G=−0.25G, when B[2:0]=111.

In another example, when B[2:0]=100, the switch 766 is closed and the switches 751, 752, 753, 754, 755 are all open. Accordingly, an equivalent resistor in the resistive processing unit 702 between the RBL 732 and the NBL 736 is R; and an equivalent resistor in the resistive processing unit 701 between the BL 730 and the PBL 734 is infinity, due to the open switches 751, 752, 753, 754, 755. In this case, an equivalent conductance of the resistive processing unit 701 is 0; and an equivalent conductance of the resistive processing unit 702 is G=1/R with a negative weight sign. As such, a total equivalent conductance of the pair of resistive processing units 701, 702 is equal to 0−G=−G, when B[2:0]=−100.

A complete relationship between the bits B[2:0] and the positive, negative and total equivalent conductance in the pair of resistive processing units 701, 702 is listed in Table I.

TABLE I

| B[2:0] | Positive | Negative | Total |
|---|---|---|---|
| 000 | 0 | 0 | 0 |
| 001 | 0.25G | 0 | 0.25G |
| 010 | 0.5G | 0 | 0.5G |
| 011 | 0.75G | 0 | 0.75G |
| 100 | 0 | G | −G |
| 101 | 0.25G | G | −0.75G |
| 110 | 0.5G | G | −0.5G |
| 111 | 0.75G | G | −0.25G |

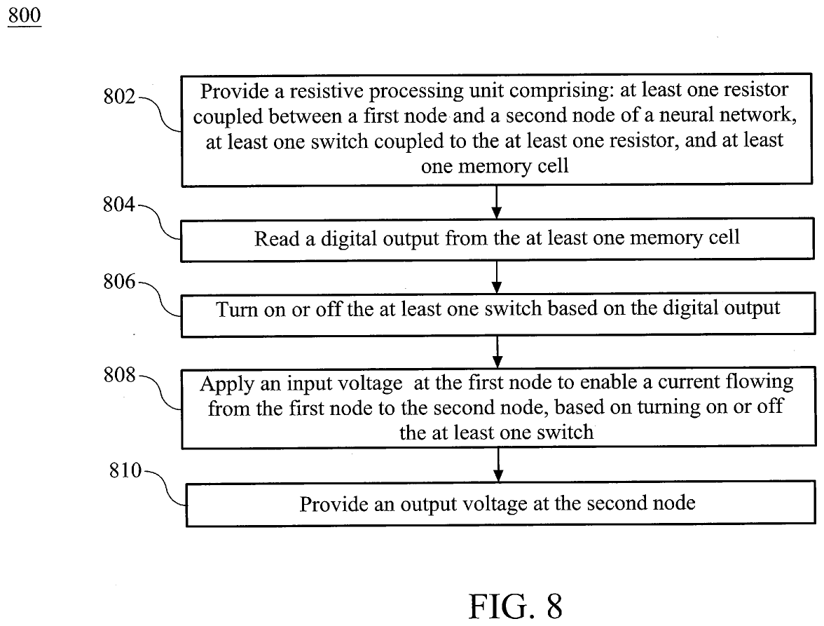

FIG. 8 shows a flow chart illustrating an exemplary method 800 for operating a resistive processing unit in a neural network, e.g. the resistive processing unit as shown in any one of FIGS. 1-7, in accordance with some embodiments of the present disclosure. At operation 802, a resistive processing unit is provided to include: at least one resistor coupled between a first node and a second node of a neural network, at least one switch coupled to the at least one resistor, and at least one memory cell. At operation 804, a digital output is read from the at least one memory cell. At operation 806, the at least one switch is turned on or off based on the digital output. At operation 808, an input voltage is applied at the first node to enable a current flowing from the first node to the second node, based on turning on or off the at least one switch. At operation 810, an output voltage is provided at the second node. In some embodiments, the output voltage may be read and provided as an input voltage to another neural network. The order of the operations shown in FIG. 8 may be changed according to different embodiments of the present disclosure.

In some embodiments, the method 800 may further comprise: turning on, based on a read enable signal during a computing mode of the neural network to enable the current, a read enable switch coupled between the first node and the at least one resistor; and turning off, based on a read enable signal during a write mode of the at least one memory cell, the read enable switch to disable the current. At least one of the first node or the second node is located on a signal line in the at least one memory cell, and the current is enabled based on turning on the read enable switch.

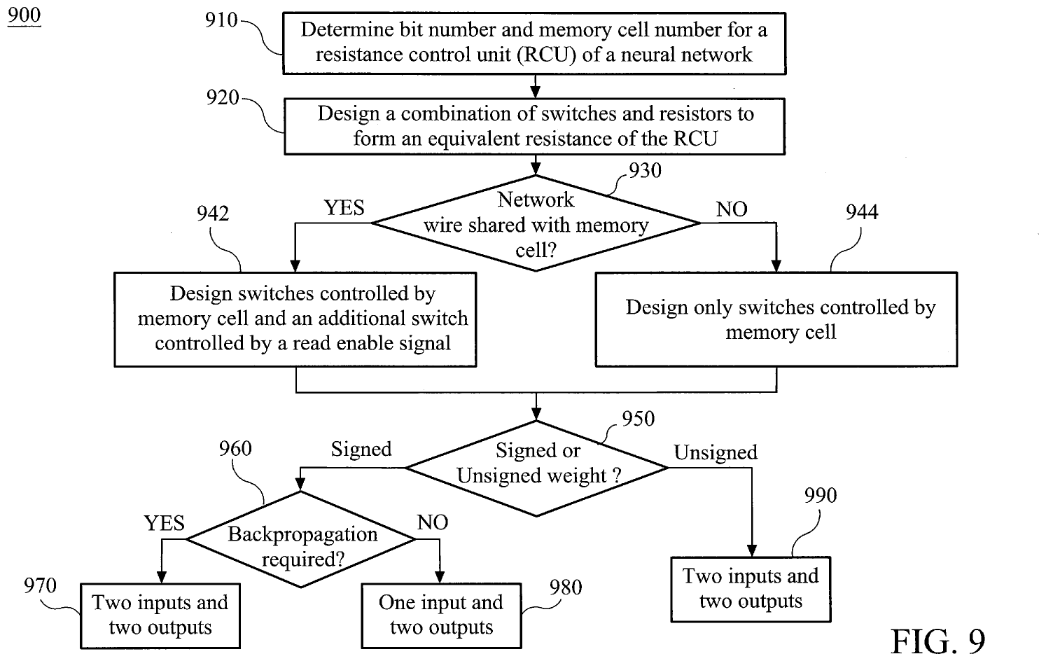

FIG. 9 shows a flow chart illustrating an exemplary method for designing a resistive processing unit in a neural network, e.g. the resistive processing unit as shown in any one of FIGS. 1-8, in accordance with some embodiments of the present disclosure. At operation 910, bit number and memory cell number are determined for a resistance control unit of a neural network. At operation 920, a combination of switches and resistors is designed to form an equivalent resistance of the resistance control unit. At operation 930, it is determined whether the wire lines of the neural network are shared with the memory cells. If so, the process goes to operation 942 to design both switches controlled by memory cells and an additional switch controlled by a read enable signal, and then goes to operation 950. If not, the process goes to operation 944 to design only switches controlled by memory cells, and then goes to operation 950 as well.

At operation 950, it is determined whether the weight provided by the resistance control unit is a signed weight or an unsigned weight. If it is an unsigned weight, the process goes to operation 990 to design the resistance control unit with two inputs and two outputs. If it is a signed weight, the process goes to operation 960 to determine whether a backpropagation is required for the neural network. If so, the process goes to operation 970 to design the resistance control unit with two inputs and two outputs. If not, the process goes to operation 980 to design the resistance control unit with one input and two outputs. The order of the operations shown in FIG. 9 may be changed according to different embodiments of the present disclosure.

In one embodiment, a resistance control unit of a neural network formed on an integrated circuit (IC) is disclosed. The resistance control unit includes: a plurality of resistors coupled between a first node and a second node of the neural network; a plurality of switches coupled to the plurality of resistors and configured for controlling a current flowing from the first node to the second node; and a plurality of memory cells configured for generating a digital output. The plurality of switches can be controlled by the digital output.

In another embodiment, an array of resistance control units is disclosed. The resistance control units are connected between row and column lines of a neural network. Each of the resistance control units includes: at least one resistor coupled between two nodes of the neural network, at least one switch coupled to the at least one resistor and configured for controlling a current flowing between the two nodes, and at least one memory cell configured for generating a digital output. The at least one switch is controlled by the digital output.

In yet another embodiment, a method is disclosed. The method includes: providing a resistive processing unit that includes: at least one resistor coupled between a first node and a second node of a neural network, at least one switch coupled to the at least one resistor, and at least one memory cell; reading a digital output from the at least one memory cell; turning on or off the at least one switch based on the digital output; applying an input voltage at the first node to enable a current flowing from the first node to the second node, based on turning on or off the at least one switch; and providing an output voltage at the second node.

While various embodiments of the present disclosure have been described above, it should be understood that they have been presented by way of example only, and not by way of limitation. Likewise, the various diagrams may depict an example architectural or configuration, which are provided to enable persons of ordinary skill in the art to understand exemplary features and functions of the present disclosure. Such persons would understand, however, that the present disclosure is not restricted to the illustrated example architectures or configurations, but can be implemented using a variety of alternative architectures and configurations. Additionally, as would be understood by persons of ordinary skill in the art, one or more features of one embodiment can be combined with one or more features of another embodiment described herein. Thus, the breadth and scope of the present disclosure should not be limited by any of the above-described exemplary embodiments.

It is also understood that any reference to an element herein using a designation such as “first,” “second,” and so forth does not generally limit the quantity or order of those elements. Rather, these designations are used herein as a convenient means of distinguishing between two or more elements or instances of an element. Thus, a reference to first and second elements does not mean that only two elements can be employed, or that the first element must precede the second element in some manner.

Additionally, a person having ordinary skill in the art would understand that information and signals can be represented using any of a variety of different technologies and techniques. For example, data, instructions, commands, information, signals, bits and symbols, for example, which may be referenced in the above description can be represented by voltages, currents, electromagnetic waves, magnetic fields or particles, optical fields or particles, or any combination thereof.

A person of ordinary skill in the art would further appreciate that any of the various illustrative logical blocks, modules, processors, means, circuits, methods and functions described in connection with the aspects disclosed herein can be implemented by electronic hardware (e.g., a digital implementation, an analog implementation, or a combination of the two), firmware, various forms of program or design code incorporating instructions (which can be referred to herein, for convenience, as “software” or a “software module), or any combination of these techniques.

To clearly illustrate this interchangeability of hardware, firmware and software, various illustrative components, blocks, modules, circuits, and steps have been described above generally in terms of their functionality. Whether such functionality is implemented as hardware, firmware or software, or a combination of these techniques, depends upon the particular application and design constraints imposed on the overall system. Skilled artisans can implement the described functionality in various ways for each particular application, but such implementation decisions do not cause a departure from the scope of the present disclosure. In accordance with various embodiments, a processor, device, component, circuit, structure, machine, module, etc. can be configured to perform one or more of the functions described herein. The term “configured to” or “configured for” as used herein with respect to a specified operation or function refers to a processor, device, component, circuit, structure, machine, module, signal, etc. that is physically constructed, programmed, arranged and/or formatted to perform the specified operation or function.

Furthermore, a person of ordinary skill in the art would understand that various illustrative logical blocks, modules, devices, components and circuits described herein can be implemented within or performed by an integrated circuit (IC) that can include a digital signal processor (DSP), an application specific integrated circuit (ASIC), a field programmable gate array (FPGA) or other programmable logic device, or any combination thereof. The logical blocks, modules, and circuits can further include antennas and/or transceivers to communicate with various components within the network or within the device. A processor programmed to perform the functions herein will become a specially programmed, or special-purpose processor, and can be implemented as a combination of computing devices, e.g., a combination of a DSP and a microprocessor, a plurality of microprocessors, one or more microprocessors in conjunction with a DSP core, or any other suitable configuration to perform the functions described herein.

If implemented in software, the functions can be stored as one or more instructions or code on a computer-readable medium. Thus, the steps of a method or algorithm disclosed herein can be implemented as software stored on a computer-readable medium. Computer-readable media includes both computer storage media and communication media including any medium that can be enabled to transfer a computer program or code from one place to another. A storage media can be any available media that can be accessed by a computer. By way of example, and not limitation, such computer-readable media can include RAM, ROM, EEPROM, CD-ROM or other optical disk storage, magnetic disk storage or other magnetic storage devices, or any other medium that can be used to store desired program code in the form of instructions or data structures and that can be accessed by a computer.

In this document, the term “module” as used herein, refers to software, firmware, hardware, and any combination of these elements for performing the associated functions described herein. Additionally, for purpose of discussion, the various modules are described as discrete modules; however, as would be apparent to one of ordinary skill in the art, two or more modules may be combined to form a single module that performs the associated functions according embodiments of the present disclosure.

Various modifications to the implementations described in this disclosure will be readily apparent to those skilled in the art, and the general principles defined herein can be applied to other implementations without departing from the scope of this disclosure. Thus, the disclosure is not intended to be limited to the implementations shown herein, but is to be accorded the broadest scope consistent with the novel features and principles disclosed herein.

What is claimed is:

1. A resistance control unit of a neural network formed on an integrated circuit (IC), comprising:
a plurality of resistors coupled between a first node and a second node of the neural network;
a plurality of switches coupled to the plurality of resistors and configured for controlling a current flowing from the first node to the second node; and
a plurality of memory cells configured for generating a digital output, wherein the plurality of switches are controlled by the digital output.

2. The resistance control unit of claim 1, wherein:
at least one of the plurality of resistors is formed by at least one gate structure and at least one gate via in the IC; and
each of the at least one gate structure and the at least one gate via comprises a polysilicon or a metal.

3. The resistance control unit of claim 2, wherein:
each of the plurality of resistors has a same resistance; and
each of the plurality of resistors is formed by connecting in series a plurality of gate structures in the IC using a plurality of gate vias on the plurality of gate structures.

4. The resistance control unit of claim 3, wherein:
the plurality of gate structures have a same width and different lengths.

5. The resistance control unit of claim 1, wherein:
each of the plurality of switches is formed by at least one transistor; and
each of the at least one transistor is connected, in series or in parallel, to at least one of the plurality of resistors.

6. The resistance control unit of claim 5, wherein:
the digital output has a plurality of bits; and
each of the plurality of memory cells is configured for storing and outputting a respective bit of the digital output.

7. The resistance control unit of claim 6, wherein:
each of the at least one transistor is controlled by one of the plurality of bits of the digital output.

8. The resistance control unit of claim 1, wherein:
each of the plurality of memory cells is a static random-access memory (SRAM) formed by six transistors.

9. The resistance control unit of claim 1, wherein:
a conductance between the first node and the second node provides a weight value associated with the neural network; and
the conductance changes linearly based on different states of the plurality of switches.

10. The resistance control unit of claim 1, further comprising:
a read enable switch coupled between the first node and the plurality of resistors, wherein:
the read enable switch is controlled by a read enable signal, and
at least one of the first node or the second node is located on a signal line in the plurality of memory cells.

11. The resistance control unit of claim 10, wherein:
the read enable switch is set to open state by the read enable signal during a write mode of the plurality of memory cells; and
the read enable switch is set to close state by the read enable signal during a computing mode of the neural network.

12. An array of resistance control units, wherein:
the resistance control units are connected between row and column lines of a neural network; and
each of the resistance control units comprises:
at least one resistor coupled between two nodes of the neural network,
at least one switch coupled to the at least one resistor and configured for controlling a current flowing between the two nodes, and
at least one memory cell configured for generating a digital output, wherein the at least one switch is controlled by the digital output.

13. The array of resistance control units of claim 12, wherein:
a conductance of each resistive processing unit between the two nodes provides a weight value associated with the neural network; and
the resistive processing units are configured for performing bidirectional communications along the row and column lines based on the weight values provided by the resistive processing units.

14. The array of resistance control units of claim 12, wherein:
each of the row lines is associated with an input of the neural network;
the column lines include a plurality of pairs of column lines;
each pair of column lines is associated with a pair of outputs of the neural network;
the resistance control units include a plurality of pairs of resistance control units; and
each pair of resistance control units is between a corresponding row line and a corresponding pair of column lines.

15. The array of resistance control units of claim 14, comprising:
a pair of resistance control units including a first resistance control unit and a second resistance control unit between a first row line and a first pair of column lines, wherein:
the first resistance control unit has a first conductance between the first row line and a first column line of the first pair, wherein the first conductance provides a positive weight associated with a first input at the first row line and a first output at the first column line,
the second resistance control unit has a second conductance between the first row line and a second column line of the first pair, wherein the second conductance provides a negative weight associated with the first input at the first row line and a second output at the second column line, and
the first resistance control unit and the second resistance control unit together provide a signed weight, based on a summation of the positive weight and the negative weight, associated with the first input and an output pair of the first output and the second output.

16. The array of resistance control units of claim 12, wherein:
the row lines include a plurality of pairs of row lines;
each pair of row lines is associated with a pair of inputs of the neural network;
the column lines include a plurality of pairs of column lines;
each pair of column lines is associated with a pair of outputs of the neural network;
the resistance control units include a plurality of pairs of resistance control units; and
each pair of resistance control units is between a corresponding pair of row lines and a corresponding pair of column lines.

17. The array of resistance control units of claim 16, comprising:
a pair of resistance control units including a first resistance control unit and a second resistance control unit between a first pair of row lines and a second pair of column lines, wherein:
the first resistance control unit has a first conductance between a first row line of the first pair and a first column line of the second pair, wherein the first conductance provides a positive weight associated with a first input at the first row line and a first output at the first column line,
the second resistance control unit has a second conductance between a second row line of the first pair and a second column line of the second pair, wherein the second conductance provides a negative weight associated with a second input at the second row line and a second output at the second column line, and
the first resistance control unit and the second resistance control unit together provide a signed weight, based on a summation of the positive weight and the negative weight, associated with (a) an input pair of the first input and the second input and (b) an output pair of the first output and the second output.

18. A method, comprising:
providing a resistive processing unit comprising:
at least one resistor coupled between a first node and a second node of a neural network,
at least one switch coupled to the at least one resistor, and
at least one memory cell;
reading a digital output from the at least one memory cell;
turning on or off the at least one switch based on the digital output;
applying an input voltage at the first node to enable a current flowing from the first node to the second node, based on turning on or off the at least one switch; and
providing an output voltage at the second node.

19. The method of claim 18, further comprising:
turning on, based on a read enable signal during a computing mode of the neural network, a read enable switch coupled between the first node and the at least one resistor, wherein:
at least one of the first node or the second node is located on a signal line in the at least one memory cell, and
the current is enabled based on turning on the read enable switch; and
turning off, based on a read enable signal during a write mode of the at least one memory cell, the read enable switch to disable the current.

20. The method of claim 18, wherein:
the neural network is formed on an integrated circuit (IC);
each of the at least one resistor is formed by connecting in series a plurality of gate structures in the IC using a plurality of gate vias on the plurality of gate structures; and
each of the at least one gate structure and the at least one gate via comprises a polysilicon or a metal.
